(19) United States
(12) Patent Application Publication
(10) Pub. No.: US 2026/0025959 A1
(43) Pub. Date: Jan. 22, 2026

(54) ENERGY EFFICIENT COOLING METHODS FOR DATA CENTERS AND SERVER RACKS

(71) Applicants: ASPEN COMPRESSOR, LLC, Marlborough, MA (US); Aspen Systems, LLC, Marlborough, MA (US)

(72) Inventor: Kang P. Lee, Sudbury, MA (US)

(73) Assignees: ASPEN COMPRESSOR, LLC, Marlborough, MA (US); Aspen Systems, LLC, Marlborough, MA (US)

(21) Appl. No.: 19/270,614

(22) Filed: Jul. 16, 2025

Related U.S. Application Data
(60) Provisional application No. 63/672,545, filed on Jul. 17, 2024.

(51) Int. Cl. H05K 7/20

(52) U.S. Cl. CPC H05K 7/20827

(57) ABSTRACT

This disclosure describes a system of distributed, compact, low height, and modular cooling systems that can potentially achieve significant reduction in energy usage by data centers, server farms and other facilities. Discrete cooling ecosystem configurations for each group of server rack, each server rack, each GPU tray containing multiple GPUs within a rack, or each of the GPUs within a GPU tray are disclosed.

### RELATED APPLICATIONS

This application claims priority under 35 U.S.C. § 119(e) to U.S. Provisional Application No. 63/672,545, filed Jul. 17, 2024, the content of which is incorporated by reference in its entirety for all purposes.

### FIELD

Disclosed embodiments generally relate to cooling systems for reducing energy usage in data centers and corresponding methods.

### BACKGROUND

There are numerous challenges currently confronting designers and operators of data centers and server farms (“data center” hereinafter), including managing processor and AI technologies which progress toward increasingly higher computational speeds and higher power requirements to operate.

### SUMMARY

According to some embodiments, a cooling system for cooling one or more server racks of a data center is provided. The cooling system may include one or more server racks that are thermally isolated from an exterior environment of a data center facility and one or more refrigeration systems arranged to be in fluid communication with the one or more server racks. The one or more refrigeration systems may each comprise a compressor, a condenser, an expansion valve, and an evaporator. The one or more refrigeration systems may be configured to dissipate heat to a location outside of the data center facility and be configured to cool each of the one or more thermally isolated server racks such that a temperature of an interior volume of the one or more server racks is less than a temperature of the exterior environment of the data center facility.

According to some embodiments, a method of cooling one or more server racks of a data center is provided. The method may comprise thermally isolating one or more server racks from an exterior environment of a data center facility. The method may further comprise placing one or more refrigeration systems of a cooling system in fluid communication with the one or more server racks. The one or more refrigeration systems may each comprise a compressor, a condenser, an expansion valve, and an evaporator. The method may further comprise dissipating heat from the one or more server racks to cool the one or more server racks using the one or more refrigeration systems such that a temperature of an interior volume of the one or more server racks is less than a temperature of the exterior environment of the data center facility.

In some embodiments, the cooling system may comprise a plurality of sets of rack-compatible modules comprising a liquid-cooled condenser module, an expansion valve-cold plate type evaporator module configured to be installed on a GPU tray comprising one or more GPU modules, and a compressor module containing one or more compressors. In some embodiments, the number of the compressor modules is equal to the number of GPU modules to be cooled in the GPU tray. The cooling system may also further comprise one or more refrigerant connections connecting the condenser, evaporator, and compressor modules.

In some embodiments, the cooling system may include one or more isolation valves configured to prevent fluid communication through the cooling system such that the modules are configured to be disconnected when the one or more isolation valves are closed, where each module of the rack-compatible modules may be mounted into the one or more server racks via one or more compartments of the server racks or by positioning each module above the one or more server racks.

In some embodiments, the cooling system may include one or more separate rack compartments for the compressor modules to be connected to a refrigerant-to-air evaporator to remove heat from an interior space of a server rack. The cooling system may also further comprise one or more cooled-liquid manifolds and one or more heated-liquid manifolds for each rack to be connected the liquid-cooled condenser module of the rack-compatible modules.

In some embodiments, a number of the compressor modules is equal to a number of GPU modules to be cooled in the GPU tray. In some embodiments, the cooling system may further comprise an additional compressor positioned in the one or more server racks for air cooling inside the one or more server racks. In some embodiments, the condenser module may be configured to be used for each of the GPU modules in the GPU tray. In some embodiments, a height of the rack-compatible modules are 2 U height compatible. In some embodiments, the compressor module may comprise a 2 U compatible horizontal compressor with 3.8 cc displacement. In some embodiments, a temperature of the evaporator may be lowered via removal of the heat using the refrigeration system such that total power used by the data center is reduced.

It should be appreciated that the foregoing concepts, and additional concepts discussed below, may be arranged in any suitable combination, as the present disclosure is not limited in this respect. Further, other advantages and novel features of the present disclosure will become apparent from the following detailed description of various non-limiting embodiments when considered in conjunction with the accompanying figures.

### BRIEF DESCRIPTION OF DRAWINGS

The accompanying drawings are not intended to be drawn to scale. In the drawings, each identical or nearly identical component that is illustrated in various figures may be represented by a like numeral. For purposes of clarity, not every component may be labeled in every drawing. In the drawings:

FIG. 1 is a chart depicting exemplary power distribution percentages for a data center;

FIG. 2 shows a schematic of a refrigeration system configured for cooling a group of server racks, according to some embodiments;

FIG. 3 shows a schematic of a distributed refrigeration system and an evaporative liquid cooler configured for cooling a group of server racks, according to some embodiments;

FIG. 4 shows a perspective view of an exemplary server rack with a cooling system, according to some embodiments;

FIG. 5 shows a schematic of a modular server rack cooling system, according to some embodiments;

FIG. 6 shows a schematic of a compressor module, according to some embodiments;

FIG. 7 shows a schematic of an evaporator module, according to some embodiments; and

FIG. 8 shows a schematic of a condenser module, according to some embodiments.

### DETAILED DESCRIPTION

The inventor has recognized and appreciated techniques for improved cooling systems that reduce the required total power to operate data centers. Such cooling systems may significantly reduce the overall power demand for data centers to cool artificial intelligence (AI) chips for training and inference of neural networks for autonomous driving and humanoid robots, graphics processing units (GPUs), and other high heat generating components and units within a data center and to maintain the temperature and humidity of the air inside a data center.

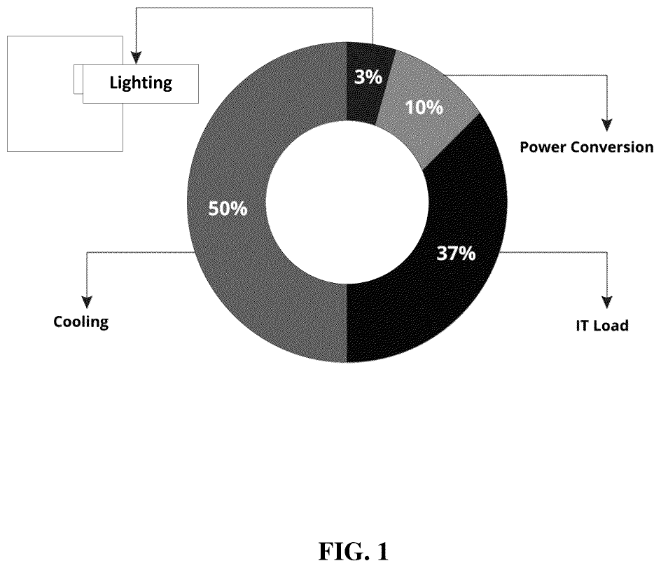

Large scale data centers use hundreds of megawatts (MW) of electrical power to the point that new data centers may be constructed close to a hydroelectric dam, nuclear power plant or a dedicated solar farm. FIG. 1 shows a representative breakdown of power usage of a typical data center. There are three major components of power uses in data centers: information technology (IT) power (37%), cooling (50%), and power conversion (10%). The remaining power is for lighting at 3%. IT power refers to power needed to run processors and other ancillary electronic and electrical components, cooling refers to power needed to cool the IT devices and the data center facility, and power conversion refers to losses incurred during high alternating current (AC) voltage conversion to lower operating voltage. The inventor has recognized that it is desirable to provide improved ways of cooling data centers to achieve savings of electric power required by data centers to operate.

To further illustrate the point, for example, as of this application, Tesla, a US based electric vehicle (EV) manufacturer that is regarded as the most advanced practical-AI (e.g., self-driving vehicles and humanoid robots) company in the world, is reported to be in the process of building a first stage of a massive data center in Austin, Texas initially with 50,000 advanced AI chips including H100 GPUs from Nvidia at $35,000 per GPU. This data center is reported to require 130 MW of electric power. It was also announced that this data center will eventually be expanded to 200,000 H100 GPUs and approximately 500 MW of required electric power. If this data center design follows the standard industry practice for data centers, 50% of 130 MW, i.e., 65 MW, of power will be allocated to cool the IT equipment and to condition the facility air at around 70 F and at or below 50% relative humidity for this initial stage with multiple air changes per hour. Based on the above, on the average, approximately 2500 Watts of electric power is needed per GPU set to operate a data center based on current practice of cooling. However, each H100 chip is known to use and produce about 700 W of heat at the peak and assuming other electronic and power components produce 300 W of heat per GPU set as a conservative measure, it is assumed a total of 1000 W of power and equivalent heat per GPU set. For a data center with 50,000 H100 or similar GPUs, the heat to be removed for the IT cooling would be 50 MW. If a compressor-based refrigeration system is used for each GPU set with a cooling coefficient of performance (COP) of 3.0, it would require 330 W of electric power, and 16.7 MW for 50,000 GPU sets.

The current practice of cooling a data center would have required 65 MW×(50% of 130 MW) to cool the facility and the IT equipment combined. Current methods used in data centers for cooling create a lot of losses such as multiple air exchanges per hour, dehumidification down below 50% relative humidity and air conditioning down to 70 F year round, mixing of air streams between the cold air aisle and the hot air aisle or spending a lot of power to condition and pump the cooling liquid to high power electronics resulting 65 MW of electrical power for cooling as was shown in the power distribution in FIG. 1.

The inventor has appreciated that for a configuration where all of the server racks are cooled by separate refrigeration system without involvement of the facility air in terms of exchanging sensible heat and latent heat, the server racks are largely and effectively sealed from the facility air in terms of heat and moisture transfer between the facility air and the server rack. Further, there would not be any need to keep the relative humidity level well below 50% to fend off corrosion and electrostatic problems of the IT components due to humidity, and there would be no need to have multiple air exchanges per hour required by many data centers. It would also make sense to insulate the roof and walls to a much higher level which was not very effective if the air exchange rate was high. Now, the air exchange rate could be much lower than practiced today and it would be just to satisfy needs of the personnel and will become even less in the future when robots take care of most of the maintenance and operation.

Let us then estimate the electric power required to cool a data center space of 300,000 sq. ft. This size is based on assumption that each server rack would house 6 H100 chip trays, and each rack would require 200 sq. ft. Let us assume that ceiling height is 20 ft. In this example, the facility air will be maintained at 70 F and 50% relative humidity which is the prevalent practice in data centers. Let us also assume that the outdoor air is at 100 F and relative humidity of 90% in the height of summer to accentuate the potential reduction of necessary cooling power. Let us also assume there are 500 employees working in the data center facility emitting 750 BTU per hour heat and 0.3 lb of water per hour. ACH (Air change per hour) of 0.1 may be sufficient for the personnel in the data center instead of energy wasting multiple air exchanges when the facility air was involved in IT cooling and dehumidification. For simplicity, let us use the following approximate methods to calculate heat gains through the building enclosures of commercial office spaces:

To estimate the electric power required for cooling the office space, we need to break down the calculations into various components as follows:
1. Building Information:
   **Area:** 300,000 sq.ft.
   **Ceiling Height:** 20 ft.
   **Volume:* Area×Height=300,000 sq. ft.×20 ft=6,000,000 cu.ft.
   **Total Heat transfer Area of the Enclosure=Flat Roof 300,000 sq.ft.+Walls for assumed 548 ft square footprint building 43,840 sq.ft. (=548×20×4)=340,840 sq.ft.
2. Indoor and Outdoor Conditions:
   **Indoor:** 70° F. and 50% relative humidity which are customary conditions of air inside data centers
   **Outdoor:** 100° F. and 90% relative humidity in the height of summer in Texas
3. Heat Load Components:
Sensible Heat Load (Q_sensible):
a. Sensible Heat Gain from Conduction through Building Enclosures

For simplicity, let us use 50% of a customary sensible heat conduction rate (1 Btu/hr/sq.ft./° F.) through enclosures of commercial office building: 0.5 Btu/hr/sq.ft./° F.

$$Q\_Enclosure = Area \times Temperature Difference \times Sensible Heat Factor = 340 , 840 sq . ft . \times 30 ° F . \times 0.5 Btu / ht / sq . ft . / ° F . = 5 , 112 , 600 Btu / hr$$

b. Internal Sensible Heat Gains from Personnel
   Number of Employees: 500
   Heat Emission per Employee: 750 BTU/hr

$$Q\_personnel = 500 \times 750 \text{Btu/hr} = 375 , 000 \text{Btu/hr}$$

c. Sensible Heat Gain due to Air Exchange:

$$Q\_ventillation = 1.08 \times Number of ACH ( \text{Air} Change per hour ) \times Total Air Volume V \times Delta T$$

Where:
   1.08 is a constant (Btu/hr-ft\hat{ }3-° F.)
   ACH=0.1
   V=volume of the building (cu.ft.)=6,000,000 cu.ft.
   Delta T=100° F.−70° F.=30° F.

$$Q\_ventilation = 1.08 \times 0.1 \times 6,000,000 \times 30 = 19,440,000 Btu/hr$$

Adding all sensible heat gains:

$$Q\_total sensible = Q\_Enclosures + Q\_Personne1 + Q\_ventillation = 5 \text{,112,600} \text{Btu/hr} \times + 375,000 Btu/hr + 19,440,000 Btu/hr = 24,927,600 Btu/hr$$

Latent Heat Load (Q_sensible):
a. Internal Gains from Occupants:

$$Q\_latent \_Personne1 = Number of Employees \times Moisture Emission per Employee per hours \times 1000 \text{Btu/lb} = 500 \times 0.3 \text{lb/hr} \times 1000 \text{Btu/lb} = 150 , 000 \text{Btu/hr}$$

b. Latent Heat Gain from 0.1 Air exchange per hour
**Calculate the moisture content difference:**
   Use psychrometric charts to find the moisture content.
   Outdoor air at 100° F. and 90% RH≈0.0350 lb moisture/lb dry air
   Indoor air at 70° F. and 50% RH≈0.00786 lb moisture/lb dry air
   Delta moisture content=0.0350−0.00786=0.02714 lb moisture/lb dry air
   Air Exchange per hour=0.1
**Calculate the latent heat:**
   Latent heat of vaporization for water≈1000 BTU/lb
   Q_latent_Air Exchange=ACH×Delta Moisture lb/ft³×1000 Btu/lb×Volume

$$V ( volume \text{of} the building ) = 6,000,000 cu.ft. = 0.1 \times 0.02714 \times 1000 \times 6,000,000 = 45,000,000 Btu/hr$$

Total Latent Heat

$$Q\_latent = Q\_latent \_Personne1 + Q\_latent \_Air Exchange = 150,000 Btu/hr + 8,142,000 Btu/hr = 45,150,600 Btu/hr$$

Total Heat to be removed

$$Q\_total = Q\_s ensible + Q\_latent = 24,927,600 Btu/hr + 45 \text{,150,000} \text{Btu/hr} = 70,077,600 Btu/hr$$

$$Assumed COP of a refrigeration system = 3$$

$$Electrical Power Needed for the compressor - based Cooling System \text{for} \text{the} building excluding Server Racks = Q\_Total \text{Btu/hr/3,412 Btu/hr/kW/} COP = 70,077,600 Btu/hr/3,412 Btu/hr/kW/ COP 3 = 6.846 kW = 6.8 MW .$$

Adding the electrical power needed for the server rack cooling, 16.7 MW, and the electrical power needed for the building excluding server racks, 6.8 MW, results in a total of 23.5 MW which compares to the 65 MW that would have been used by conventional cooling method. This is a 41.5 MW reduction representing a 67% reduction for cooling power of a data center. Under the assumed operating conditions which may occur in the height of the summer, the total power use for the data center drops from 130 MW using a conventional cooling method to 88.5 MW representing 32% decrease in total power used for the data centers if the cooling methods disclosed herein are employed.

In addition, one may further reduce the power consumption for data center cooling further by better insulating the building enclosure, reducing the height of the building, increasing the set temperature for example from 70 F to 80 F, increasing the set humidity level for example from 50% to 70% since there is no need to keep them at or below 50% any longer to prevent damages to the IT equipment due to humidity in the conventional data center cooling method and server racks exposed to the facility air.

The inventor has recognized that there exists obstacles to implement the above- mentioned cooling methods with “sealed” server racks independently and directly cooled by compressor-based distributed refrigeration systems and a separate HVAC system for the facility housing the server racks of data centers despite the sizable potential savings. The reliability of compressor-based cooling systems, maintenance requirements for a massive number of lines and components of refrigeration equipment, significant refrigerant leakages that are endemic with refrigerant systems in general especially large systems with long refrigerant lines, valves, connections, etc., redundancy considerations, additional capital expenses, etc., just to name a few. Another major factor is the inertia inherently present in the industry for systems that have been working reliably despite the huge power requirements.

The inventor has appreciated that there is a potential to reduce the total power consumption of a data center by turning to a distributed cooling of “sealed” individual server racks and/or individual high heat generating GPUs using a dedicated compressor based refrigeration system, and one can envision a drastic reduction of total energy consumption of a data center so long as the initial investment and maintenance requirements for the distributed refrigeration system can be accepted or tolerated in light of its numerous advantages, and most of all, significant reduction of operating costs for the overall data center. The data center cooling requirement will only get much higher in the future unless a revolutionary advancement in chip/processor technology is introduced in the market to reduce the power requirement while at the same time managing the expected increase in the computation capabilities of GPUs.

The inventor has recognized that there exists a need for the effective high density cooling methods for the high-power consuming and high heat generating electronics components such as AI GPUs whose cooling requirements are fast increasing at the same time their physical dimensions are shrinking. For example, there is a GPU with 1 kW of cooling requirement and with eight of them combined, a total of 8 kW of cooling from one tray of a server rack with very small heat transfer areas and volume. Current methods either fall short already, quite inefficient, or will be become obsolete soon. For example, a state-of-the art GPU processor may require up to 1 kW of cooling needs with small footprint of ˜4 square inches. Another advanced GPU has 300 W of cooling needs with only 1 square inch footprint. It is expected that the foreseeable trend is for the GPU cooling power requirement to increase rapidly further while the cooling power density keeps increasing. To date, water/liquid cooling method has been the cooling mode of choice for these high powered GPUs. However, with its relatively mediocre heat transfer coefficient of liquid to surface heat transfer, the use of evaporative heat transfer with up to two orders of magnitude increase in cooling power density is called for. Cold plate type evaporators with close thermal contact to the GPUs is an obvious choice in terms of cooling power per unit area and also the compactness of the evaporator itself. It is also desirable to use compressors that are small enough to house the cooling system components in a low height system given the various width and depth needs for a given compressor application (e.g., 2 U, 3 U, 4 U, etc.). As used herein, the letter “U” such as in 1 U, 2 U, 3 U, 4 U, etc., refers to a measurement of a rack unit defined as 1.75 inches.

The inventor has recognized that there exists a need to find ways to protect the extremely high-priced ($35,000 per GPU, $280,000 per tray of 8 GPUs, and $840,000 per server rack holding three sets of tray) GPU's prematurely in cases of cooling system malfunction by immediately detecting and alerting the server rack control system to turn off the power to the affected GPUs before turning off the cooling circuit suspected of malfunctioning or beginning to show a performance deterioration and bypass that particular GPU circuit until it is fixed while safely protecting the GPUs for reuse after the maintenance is completed.

The inventor has recognized that there is a need to shrink the size of the cooling system in terms of its footprint and the height so that each rack and its cooling system become as compact as possible to increase the number density of server racks per unit area of a data center.

The inventor has also recognized that there is a need to find ways to reduce maintenance and need for reducing the total refrigerant charge and annual leakage rates for the data center and also the lengths of connecting refrigeration lines and the leakages.

Current trend shows rapidly increasing demand for high performance processors such as advanced AI GPU's, especially for AI training and inference computing for autonomous driving and humanoid robots to be used. Also, there is an economic and infrastructure need for effective utilization of the floor space within data center buildings and other facilities in the context of reducing the overall energy cost of data center operations, a bulk of which is the energy cost of cooling the electronics, and capital cost of the building and its cooling needs. For example, even a several degree increase in data center air temperature, and even a 10% increase in relative humidity levels for the facility air, would result in significant reduction of the overall energy cost for the data center. This leads to the idea of cooling the racks using compressor-based refrigeration systems without involving the facility air.

A set of approaches is described below in which the individual racks and the electronics within can be cooled independent of the facility air by using cooling systems that dump heat into the liquid loop connected to the rooftop chilled liquid system. Personnel can work within air-conditioned pods with on-demand air-conditioned pods while most of the data center can be maintained at much higher air temperature such as 30 C and reasonable humidity level in contrast to the current practice of 70 F and low humidity level of lower than 50% while air exchange per hour is quite high, which are prevalent operating conditions. As we move into a stage when humanoid robots perform most of the maintenance functions within the data center, even higher energy cost reduction may be achieved by further relaxing of the air temperature and humidity requirements within the vast data center buildings.

The inventor has recognized a need to achieve the goals outlined above to design an efficient, modular and compact distributed cooling system concept for individual server racks that are largely independent of the facility air while providing comfortable enough working environment for personnel.

There are many methods that the inventors have recognized to implement the cooling methods disclosed herein for the server racks of data centers that are cooled and humidity controlled separate from the rest of the data center. More specifically, the inventors have found that the following may be used: multiple condenser units or evaporative liquid cooler located on the roof of a data center, outside the walls near the particular group of server racks, or outside on the ground to reduce the refrigerant connection line lengths to the server racks, each with a redundant or multiple parallel set of condenser units with automatic switching in case one unit fails.

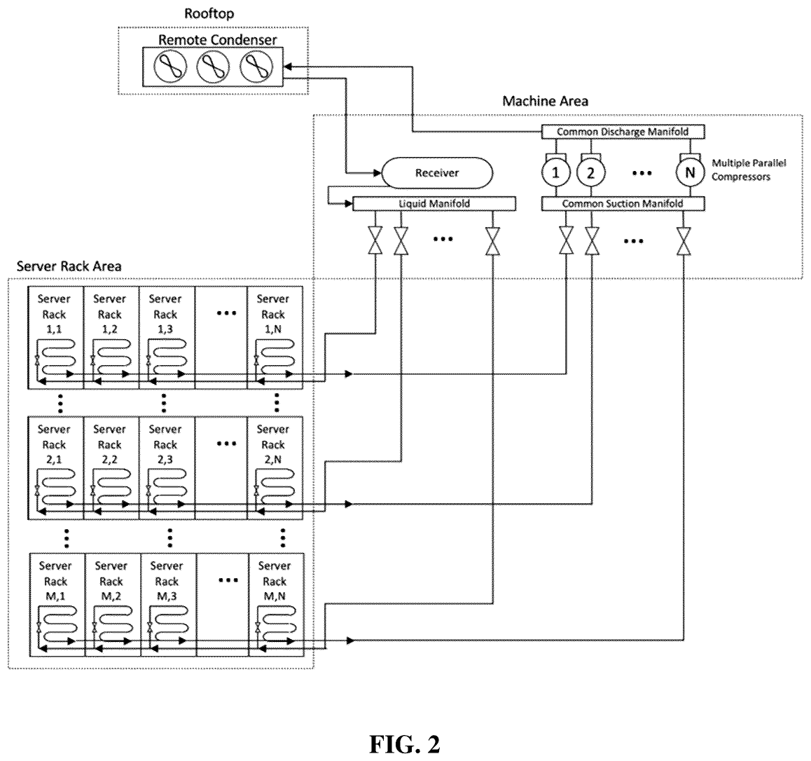

FIG. 2 shows a schematic embodiment of a so-called multiplex refrigeration system designed to cool a group of server racks. That is, the refrigeration system may be arranged to be in fluid communication with the server racks to provide cooling to an interior volume of the server racks such that a temperature of the interior volume is less than a temperature of the exterior environment of the data center facility. For example, if there are 10,000 server racks in a data center, a group consisting of 100 server racks can be served by one such subsystem and there will be 100 subsystems. There is a common suction manifold that feeds suction gas to multiple compressors mounted in parallel and the multiple compressors discharge to a common discharge manifold. The hot compressed refrigerant gas goes into a rooftop condenser and gets cooled by ambient air flow and condenses to liquid state. The liquid refrigerant collects in the common liquid refrigerant manifold from which the refrigerant goes through an expansion process through an expansion valve and flows into evaporators at lower pressure and low temperature and turns into vapor in the evaporators by absorbing heat thereby cooling the server racks and the heat generating components within. As used herein, the suction and discharge manifolds may be referred to as heated-liquid manifold(s) whereas the liquid refrigerant manifold may be referred to as a cooled-liquid manifold. For each server rack, there can be one expansion valve for the entire rack, an individual GPU tray, or each GPU depending on the needs.

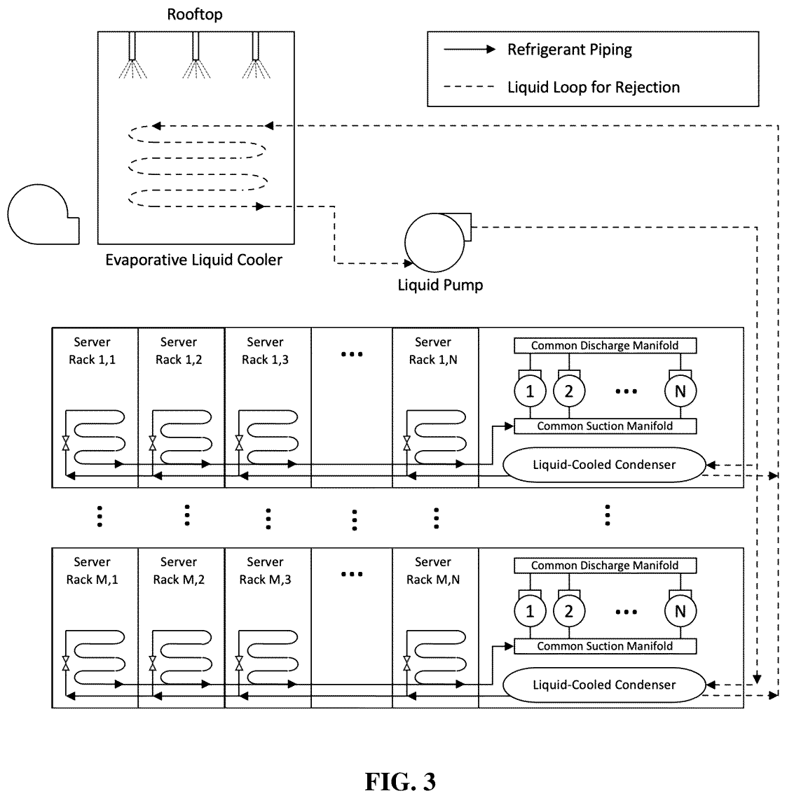

FIG. 3 shows a schematic embodiment of a distributed refrigeration system supported by a rooftop evaporative liquid cooler designed to cool a group of server racks. In this case the cooled liquid from the rooftop evaporative liquid cooler supplies the cooled liquid close to where the particular group of server racks are located. This design greatly reduces the lengths of refrigerant lines between components, total refrigerant charge and annual leakage rate compared to the system shown in FIG. 2. There is a common suction manifold that feeds suction gas to multiple compressors mounted in parallel and the multiple compressors discharge to a common discharge manifold. The hot compressed refrigerant gas goes into a liquid cooled compact condenser and gets cooled by fluid flow from the rooftop evaporative fluid cooler and condenses to liquid state. The liquid goes through expansion process through a first stage expansion valve to lower the pressure and the temperature of the expanded liquid and goes through secondary expansion before flowing into evaporators at lower pressure and low temperature and turns into vapor in the evaporators by absorbing heat from and thereby cooling the server racks and the heat generating components within. For each server rack, there can be one expansion valve for the entire rack, an individual GPU tray, or each GPU depending on the needs.

### A Compact and Modular Low Height Cooling System for Server Racks

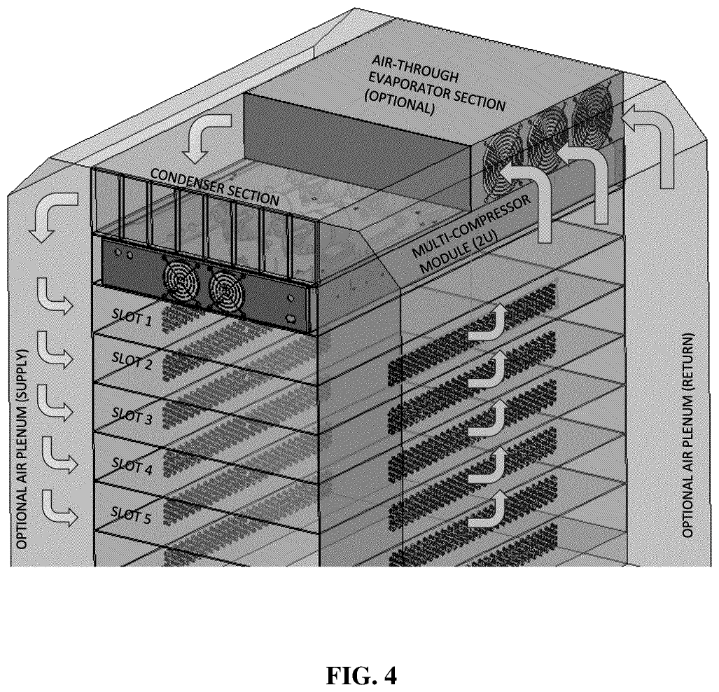

As an ultimate case of distributed compressor-based refrigerant system, one can envision a 2 U (3.5 inch) height compatible evaporator module using a cold plate configuration, compressor, condenser modules that can slide into 2 U slots of server racks, or on top of the server rack. FIG. 4 shows a rendering of the top portion of a server rack showing a common condenser for the entire server rack and a refrigerant-to-air evaporator for cooling the recirculating air inside the server rack. In general, the condenser could be a common liquid- cooled condenser for the server rack containing multiple IT trays that can be installed on top, near the side of the rack, in a nearby rack, or hanging from the ceiling. It could also be individual 2 U compatible liquid-cooled condenser taking care of each tray or each GPU. Since there will be sources of heat inside the server rack other than the heat generated by GPUs that can be readily removed by air cooling, a refrigerant-to-air evaporator can be placed in one or two of the rack trays or on top of the sever rack using one of the nine (8 plus one optional one) compressors from the compressor module or there can be a separate compressor tray with appropriate number of compressors to serve the refrigerant-to-air evaporator for recirculating air cooling for the inside of the server rack. In a 22 U server rack, one can assume installing 6 sets of 2 U tray sets consisting of an IT tray each containing eight 1 kW GPUs and eight cold plate type evaporators to absorb 1 kW of heat from each GPU, a 2 U compressor tray with nine 1 kW compatible compressors, eight of them for GPUs and one connected to air cooled evaporator for removing the remaining heat from inside the sealed server rack by recirculating air, one 2 U compatible water cooled condenser tray each capable of dumping 8 kW or eight smaller 1 KW of heat into the cooling liquid loop. As used herein, a “sealed” server rack may refer to a server rack that is thermally isolated from an exterior environment of a data center facility. The condenser tray can be one common condenser for all six evaporators or six individual condensers all connected to the same cooling water loop as shown in FIG. 4. These rack-mounted cooling system configurations greatly reduce line losses owing to short refrigeration line connection distances and result in high COP by utilizing inherently efficient and reliable miniature BLDC rotary compressors. So, each set requires three 2 U slots. For 6 such sets, eighteen (18) 2 U slots will be occupied out of 22 slots. That would leave four 2 U slots which slots can be used for internal cooling of the server rack and for other functions. This compact modular distributed configuration described herein has become possible due the availability of an extremely reliable and energy efficient horizontal 3.8 cc BLDC rotary compressors, 8 or 9 of which can be installed within a 2 U tray and each compressor cooling circuit will cool one 1 kW GPU with high COP. In the future, as the cooling requirements increase further, larger capacity horizontal rotary compressors could be used in 3 U, 4 U, or higher trays.

A compact and modular low height cooling system for server racks consisting of a low-height, highly efficient multi-compressor module, a low height condenser module, and a cold-plate evaporator module that can be co-located in the GPU module, and refrigerant connections between appropriate modules that may be disconnected for maintenance. The modular cooling system is intended for high power density cooling, reduction of overall energy cost for the server racks and eventually the entire facility, case of maintenance, agile protection of expensive processors, higher MTBF of cooling system overall and the servers, rapid and convenient replacement of malfunctioning cooling components without disrupting the remainder of the rack operation, and limiting or eliminating the need to increase the footprint of the server racks resulting in high utilization of floor space. The modular, low height cooling system utilizes multiple parallel and discrete cooling circuits with each cooling circuit providing cooling to at least one high power processor such as 1 kW GPU or 8 kW module in a tray. Each compressor module may consist of multiple compact rotary compressors, horizontal or vertical, housed in as low height compartment as required by the rack configuration such as a 2 U, 3 U height, or taller compressor compartment depending on the cooling capacity requirements. The condenser module consists of a liquid cooled condenser whose cooling liquid circuit is connected to the roof-top liquid-to-air cooling system which serves multiple distributed cooling systems. The evaporator module consists of an expansion valve, refrigerant line and cold plate type evaporator thermally connected to and to remove the heat generated by a high-power processing unit within the processor tray/compartment of the server rack.

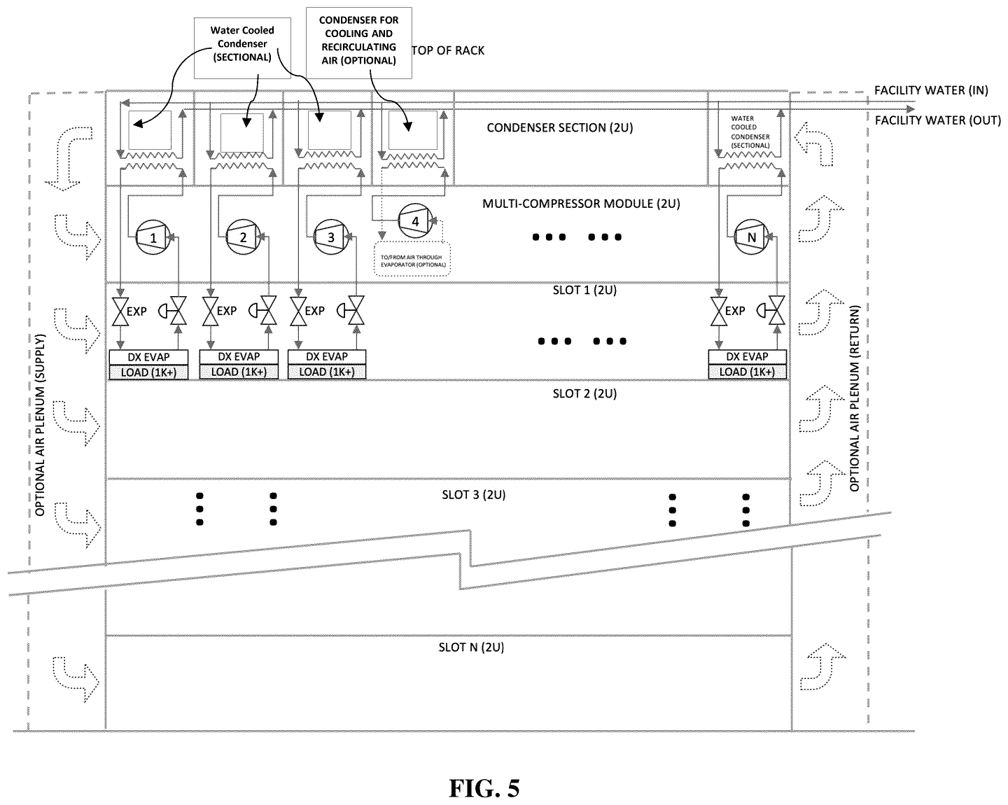

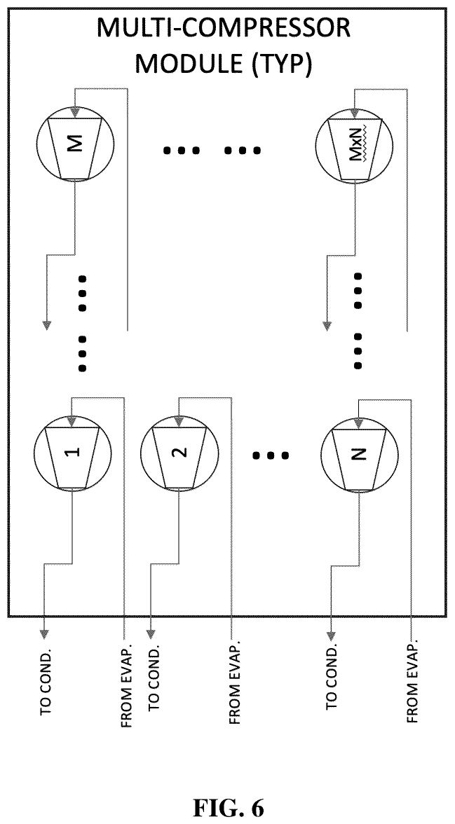

FIG. 5 is a schematic embodiment of the proposed modular server rack cooling system. The modular server rack cooling system may include one or more rack-compatible modules mounted into the server racks (e.g., via one or more compartments of the server racks or by positioning each module above the one or more server racks). The rack cooling system as shown consists of a condenser module (2 U height as shown or a taller and larger one depending on the total cooling loads of the GPU tray) in one of the slots of the server rack, followed by a 2 U height multi-compressor module (for example, with 8 miniature 3.8 cc horizontal compressors each with 1 kW cooling capacity for 8 compressors, or larger compressors requiring a 3 or 4 U height unit for higher cooling capacity depending on the requirement) in order to make the compressor compartment as of low height as possible within reason. An evaporator module (cold plate type evaporator/expansion valve/connecting line as shown) within the tray housing for example with 8 of 1 kW GPUs and an 8 kW total cooling needs for the tray as in the case of 2 U module. The condenser unit is hooked up to and dissipates heat to the liquid loop connected to the rooftop liquid cooling system. The condenser module can be of a sectional design to handle each 1 kW cooling circuit separately, each 8 kW rack separately, or a monolithic condenser with a common plenum for the selected cooling circuits. The decision on which condenser design to adopt will hinge on the consideration of maintenance cost and duration, downtime cost, and case of isolation of the circuit to protect the high-priced GPUs. The compressor module shown in FIG. 6 is a 2 U height unit with eight (8) horizontal rotary compressors each with 1 kW cooling capacity, each of them cooling 1 kW GPUs with cold plates. We can use an extra bay in the server rack to have sufficient number of compressors to be connected to the refrigerant to air evaporator to cool the inside air of the sealed server rack and remove the remainder of the heat generated other than by GPUs. Shut off or isolation valves are to be placed at appropriate locations for each compressor circuit to make it convenient to remove, service or replace the malfunctioning cooling circuit. A multiple set of condenser units or a single large condenser unit and the compressor unit can be installed above the rack or within the rack and its cold plate connectors can be installed within each GPU module. Also as shown in FIGS. 4 and 5, there are air recirculating plenums connected to an optional air-to-refrigerant evaporator on top, or above the rack or hanging from the ceiling to remove any remaining heat from the rack to form a closed cooling system for the rack interacting with the rooftop liquid cooling system so as not to interact with the data center air in any meaningful degree. The ideal place to place the plenums could be front and back where most racks already have perforations of approximately 64% porosity for air flow, or with special designs, left and right of the racks as shown in FIG. 5, though other percentages of porosity are contemplated. In the former case, there will have to be a liftable or removable front cover to form the air inlet plenum and air outlet plenum in the back which may pose a problem for all the power, refrigerant connections and cooling liquid connections. In the latter case, the plenums would be fixed plenums with the customary 64% perforations in the side walls of the server rack and measures to remove obstacles and facilitate the cooling air flow sideways will be needed for the trays. With all of the heat generated within the rack taken care of by the proposed direct compressor-based refrigeration system for the server racks, the data center air can be kept at higher temperatures, for example at 80 F for example instead of the usual 70 F and perhaps more importantly the relative humidity levels can be set much higher such as 70% instead of the current practice of at or below 50%, resulting in additional savings for the data center operation especially if the Air Change per Hour is required to go higher than assumed in the above example for any reason.

In short, using the compact rotary compressor based distributed cooling system with direct heat removal from the substantially-sealed server racks, which are the major source of the heat within a data center, and using a separate HVAC system for the remainder of the facility, results in a lower overall power requirement based on state-of-the-art data center cooling practices with a lower amount of potential refrigerant leakages due to relatively short lengths of refrigerant lines, and a higher degree of reliability rating for the data center. Also, most of heat generated within the rack can be dumped to condenser units located outdoors or the rooftop liquid cooling loop which may be in data centers already. This would make retrofitting the cooling systems disclosed herein into an existing data center much easier and cost effective. Using the cooling systems disclosed herein, there will be a high likelihood of noticeable reduction in total energy cost for data centers as the example calculation demonstrated.

FIG. 6 shows a schematic embodiment of a compressor module with multiple (N) compressors each of which can be dedicated to cool one GPU, multiple GPUs and, as an obvious option, in order to make the server rack cooling totally independent of the data center, a separate refrigerant to air evaporator to cool the recirculating air stream air inside the server rack to pick up heat generated by miscellaneous heat generating components inside the server rack and dehumidify the air inside the server rack as well. For example, to achieve a total of 8 kW of cooling within a 2 U height compressor module installed in a server rack, a configuration using eight (8) horizontal rotary BLDC compressors with 3.8 cc displacement would be sufficient to cool the eight (8) GPUs. Each compressor will form a cooling circuit for one 1 kW GPU. In the future, if the cooling requirement per compressor cooling circuit increases to 2 kW, 3 kW or higher, one can increase the height of the compressor module from 2 U to 3 U or taller as needed by larger capacity compressors. Having a separate cooling loop for each GPU may initially cost more than having a larger compressor serving multiple GPUs however, but it comes with multiple advantages so long as these miniature compressors are reliable efficient with a long enough mean time between failures (MTBF).

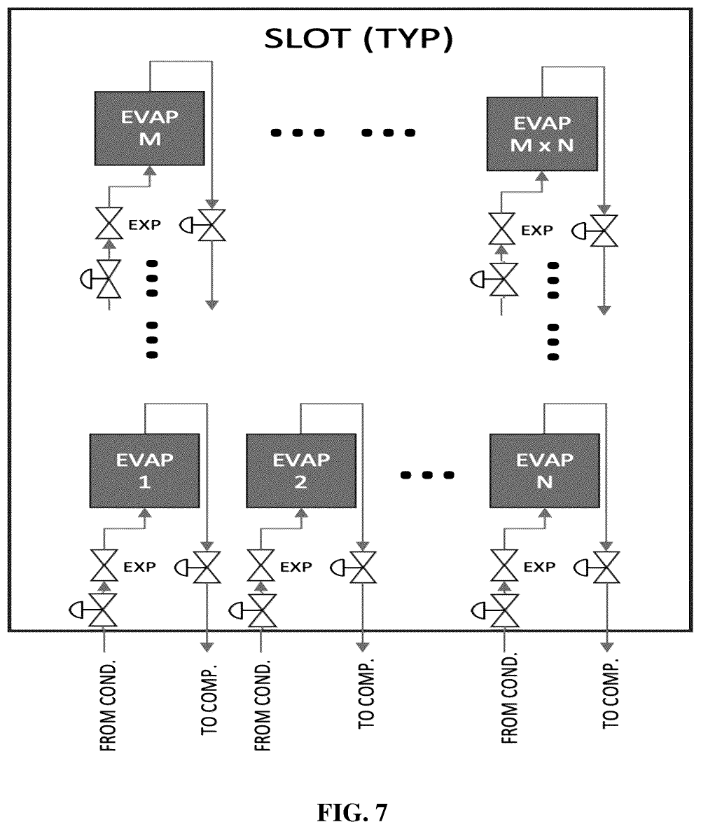

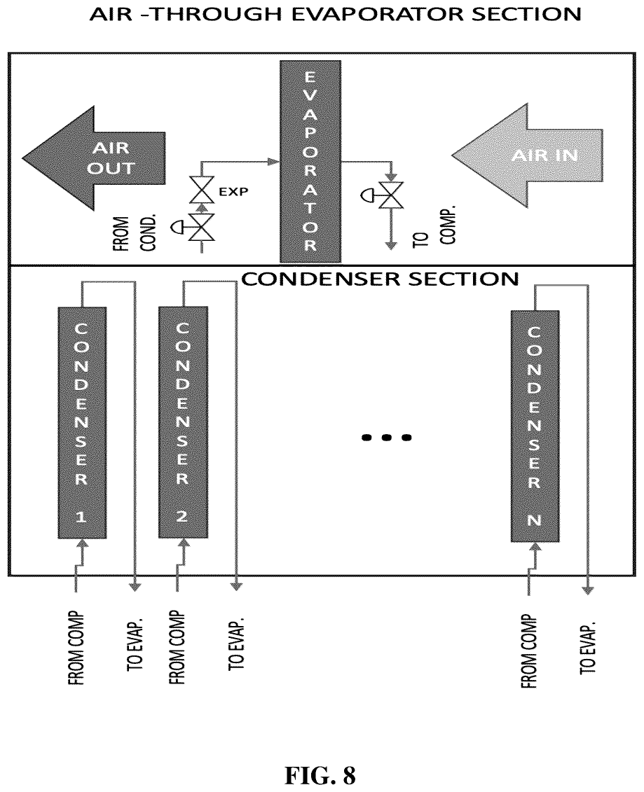

Referring back to the advantages of discrete cooling circuit for each GPUs: failure of one cooling circuit can be easily detected and the server controller can be programmed to bypass failed GPU circuits by turning off the power to the affected GPU immediately to protect the high-priced GPU, while affected cooling system is being shut down, cause of the failure gets diagnosed and malfunctioning component is repaired or replaced. This gives a better protection of the valuable GPU and fine-tuned single GPU level redundancy and increased reliability rating for the data center itself for the data center to be able to charge higher rates to customers of the data center services. Compared to this type of GPU level redundancy and resiliency system, consequences of failure of a one-compressor based cooling system cooling multiple GPUs, cooling the entire rack, let alone a group of server racks, or the entire facility increase as the degree of distributed cooling gets reduced. Of course, the data center designers and operators will need to perform cost/risk/reward analysis to determine the level of distributed cooling scheme from GPU level, multi-GPU level, server rack level, multi-server rack level, etc. FIG. 7 shows a schematic of an embodiment of an evaporator module installed within a compartment housing with processors that generate N kW of cooling in total. As schematically shown in FIG. 7, there could be isolation/shutoff valves or a quick disconnect type connectors in the refrigeration lines throughout the system for ease of isolation, replacement, maintenance or repair of each refrigerant circuit or for each compressor, evaporator or condenser modules. FIG. 8 shows a schematic of an embodiment of a liquid cooled condenser module installed to dissipate heat from GPUs that generate N kW in total. As partially shown in FIG. 8, there are isolation/shutoff valves or quick-disconnect type connectors in the refrigeration lines throughout the system for ease of isolation, replacement, maintenance or repair of each refrigerant circuit or for each compressor, evaporator or condenser modules. Also shown in FIG. 8 is a refrigerant-to-air evaporator next to the condenser unit that will be connected to the air plenum as was shown in FIG. 2 to remove remnant heat from and dehumidify the air within the server rack after bulk of the heat from the high-power GPUs is removed by individual cold plates. The refrigerant-to-air evaporator can be placed on the same level as the condenser as shown or it can be placed at different locations altogether such as an empty rack section, directly above the server rack under the condenser unit or elsewhere appropriate. Advantages of the proposed distributed cooling systems:

### Overall Lower Power Requirement Energy Cost for Cooling for Data Centers

Since each high power and high per area power density processor (GPU) is cooled within the server rack dumping heat to the cooling water loop connected to the rooftop liquid cooling system, the air temperature inside the data center can be kept higher than current practice such as 80 F instead if 70 F. Or, if air-conditioned pods can be introduced within the data center for the support personnel, the data center temperature can be further increased and the humidity level can be increased as well to save energy use by the data center. The wasted heat from the pod cooler also can be dumped into the cooled water loop so as to complete the energy saving measures.

The rack cooling system can quickly respond to the varying cooling needs of the GPUs and the remainder of the electronics inside the server racks saving energy and longevity of the GPUs and cooling system components such as the compressor, the evaporator fan etc., rather than running the compressor or the evaporator fan at full blast or fixed speed all the time. Because of the modularity of the components, malfunctioning ones can be readily swapped out reducing down time and maintenance cost.

The GPUs tend to run faster when effectively cooled by a well-designed cold plate utilizing evaporative heat transfer and low pressure drop of refrigerants.

### Summary of Advantages and Salient Characteristics

1. Significant reduction in power needed to operate a data center by removing most of the heat from each server rack through the use of compressor based refrigeration systems with high coefficient of performance to the cooling water loop connected to the outdoor cooled liquid system and without the use of the building air to cool the server racks, enabling much higher set points for the data center air temperature and humidity and further reduction of power usage.
2. Chips and processors in general are known to be able to run at higher clock speeds when the operating temperature goes down. However, when the evaporator temperature is lowered, the coefficient of performance goes down, meaning it will increase the power needed to run the compressor-based cooling system, and vice versa. In using the cooling methods disclosed herein, the evaporator temperature may be adjusted to improve or optimize the overall performance of the data center by balancing the GPU speed and power usage depending on the judgment of the data center operator.
3. Efficient use of floor space by stacking up within, on or above the rack using low height modules housing compressors, condensers, evaporators, etc. and relatively short refrigerant and cooled water lines with shutoff valves that can be connected preferably in the back of the server rack.
4. Ease of maintenance and replacement of malfunctioning cooling components, GPUs, and liquid lines modular units housing compressors, condensers, evaporators, etc. and refrigerant lines with shutoff valves that can be connected readily in the back of the server rack.
5. Longer MTBF of cooling systems and GPUs.
6. Agile protection and preventive measures to prevent damages to the GPUs.
7. Robust computation operation with longer uninterrupted operation for each slot owing to isolation of malfunctioning cooling circuit for each processing unit allowing the rest of the units to operate with minimal disruption.

While the present teachings have been described in conjunction with various embodiments and examples, it is not intended that the present teachings be limited to such embodiments or examples. On the contrary, the present teachings encompass various alternatives, modifications, and equivalents, as will be appreciated by those of skill in the art. Accordingly, the foregoing description and drawings are by way of example only.

1. A cooling system comprising:
one or more server racks, wherein the one or more server racks are thermally isolated from an exterior environment of a data center facility;
one or more refrigeration systems arranged to be in fluid communication with the one or more server racks, wherein the one or more refrigeration systems each comprise:
a compressor;
a condenser;
an expansion valve; and
an evaporator;
wherein the one or more refrigeration systems are configured to dissipate heat to a location outside of the data center facility, wherein the one or more refrigeration systems are configured to cool each of the one or more thermally isolated server racks such that a temperature of an interior volume of the one or more server racks is less than a temperature of the exterior environment of the data center facility.

2. The cooling system of claim 1, wherein the cooling system comprises a plurality of sets of rack-compatible modules comprising a liquid-cooled condenser module, an expansion valve-cold plate type evaporator module configured to be installed on a GPU tray comprising one or more GPU modules, and a compressor module containing one or more compressors, and further comprising one or more refrigerant connections connecting the condenser, evaporator, and compressor modules.

3. The cooling system of claim 2, further comprising one or more isolation valves configured to prevent fluid communication through the cooling system such that the modules are configured to be disconnected when the one or more isolation valves are closed, wherein each module of the rack-compatible modules is mounted into the one or more server racks via one or more compartments of the server racks or by positioning each module above the one or more server racks.

4. The cooling system of claim 2, further comprising one or more separate rack compartments for the compressor modules to be connected to a refrigerant-to-air evaporator to remove heat from an interior space of a server rack, and further comprising one or more cooled-liquid manifolds and one or more heated-liquid manifolds for each rack to be connected the liquid-cooled condenser module of the rack-compatible modules.

5. The cooling system of claim 2, wherein a number of the compressor modules is equal to a number of GPU modules to be cooled in the GPU tray.

6. The cooling system of claim 5, further comprising an additional compressor positioned in the one or more server racks for air cooling inside the one or more server racks.

7. The cooling system of claim 2, wherein the condenser module is configured to be used for each of the GPU modules in the GPU tray.

8. The cooling system of claim 2, wherein a height of the rack-compatible modules are 2 U height compatible.

9. The cooling system of claim 8, wherein the compressor module comprises a 2 U compatible horizontal compressor with 3.8 cc displacement.

10. The cooling system of claim 1, wherein a temperature of the evaporator is lowered via removal of the heat using the refrigeration system such that total power used by the data center is reduced.

11. A method of cooling one or more server racks of a data center, the method comprising:
thermally isolating one or more server racks from an exterior environment of a data center facility;
placing one or more refrigeration systems of a cooling system in fluid communication with the one or more server racks, wherein the one or more refrigeration systems each comprise a compressor, a condenser, an expansion valve, and an evaporator;
dissipating heat from the one or more server racks to cool the one or more server racks using the one or more refrigeration systems such that a temperature of an interior volume of the one or more server racks is less than a temperature of the exterior environment of the data center facility.

12. The method of claim 11, further comprising a plurality of sets of rack-compatible modules comprising a liquid-cooled condenser module, an expansion valve-cold plate type evaporator module configured to be installed on a GPU tray comprising one or more GPU modules, and a compressor module containing one or more compressors, and further comprising one or more refrigerant connections connecting the condenser, evaporator, and compressor modules.

13. The method of claim 12, further comprising preventing fluid communication through the cooling system using one or more isolation valves such that the modules are disconnected when the one or more isolation valves are closed.

14. The method of claim 13, wherein each module of the rack-compatible modules is mounted into the one or more server racks via one or more compartments of the server racks or by positioning each module above the one or more server racks.

15. The method of claim 12, further comprising removing heat from an interior space of a server rack using a refrigerant-to-air evaporator connected to one or more separate rack compartments for the compressor modules.

16. The method of claim 15, further comprising connecting one or more cooled-liquid manifolds and one or more heated liquid manifolds to the liquid-cooled condenser module of the rack-compatible modules.

17. The method of claim 12, wherein a number of the compressor modules is equal to a number of GPU modules to be cooled in the GPU tray.

18. The method of claim 17, further comprising positioning an additional compressor in the one or more server racks for air cooling inside the one or more server racks.

19. The method of claim 12, wherein a height of the rack-compatible modules are 2 U height compatible.

20. The method of claim 11, wherein dissipating heat from the one or more server racks lowers a temperature of the evaporator such that total power used by the data center is reduced.
